(19) United States
(12) Patent Application Publication
(10) Pub. No.: US 2026/0333819 A1
(43) Pub. Date: Oct. 22, 2026

(54) SELF-ALIGNED BACKSIDE CONTACTS IN CFETS AND THE METHODS OF FORMING THE SAME

(71) Applicant: Taiwan Semiconductor Manufacturing Co., Ltd., Hsinchu (TW)

(72) Inventors: Wei-De Ho, Hsinchu (TW); Zhi-Chang Lin, Zhubei (TW); Guan-Ren Wang, Hsinchu (TW); Yu-Hsien Chiang, Hsinchu (TW); Ju-Yu Hoo, Hsinchu (TW)

(21) Appl. No.: 19/721,238

(22) Filed: Jun. 26, 2026

Related U.S. Application Data
(63) Continuation of application No. 19/005,360, filed on Dec. 30, 2024.
(60) Provisional application No. 63/699,911, filed on Sep. 27, 2024.

(51) Int. Cl. H10D 64/23; H10D 84/01; H10D 84/83

(52) U.S. Cl. CPC H10D 64/254; H10D 84/0149; H10D 84/832

(57) ABSTRACT

A method includes forming a lower source/drain region over a substrate, forming a gate stack aside of the lower source/drain region, forming an upper source/drain region over the lower source/drain region, performing a backside thinning process to thin the substrate and to reveal a sacrificial region, removing the sacrificial region to reveal the lower source/drain region, and forming a backside contact plug to electrically connect to the lower source/drain region.

### PRIORITY CLAIM AND CROSS-REFERENCE

This application is a continuation of U.S. patent application Ser. No. 19/005,360, filed on Dec. 30, 2024, entitled “SELF-ALIGNED BACKSIDE CONTACTS IN CFETS AND THE METHODS OF FORMING THE SAME,” which claims the benefit of the provisionally filed U.S. Patent Application No. 63/699,911, filed on Sep. 27, 2024, and entitled “Self-aligned CFET BMD,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 9 are views of intermediate stages in the formation of CFETs and backside connection structures in accordance with some embodiments.

FIGS. 10 through 16 are views of intermediate stages in the formation of CFETs and backside connection structures in accordance with alternative embodiments.

FIGS. 17 through 20 are views of intermediate stages in the formation of CFETs and backside connection structures in accordance with alternative embodiments.

FIG. 21 illustrates a flow chart for forming CFETs and backside connection structures in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Complementary Field-Effect Transistor (CFET), the backside connection structures and the method of forming the same are provided. In accordance with some embodiments, a CFET is formed from a front side of a wafer, and the backside connection structures are formed from the backside of the wafer. The formation of the backside connection structures includes pre-forming sacrificial regions to align to lower source/drain regions, removing the sacrificial regions to expose lower source/drain regions, and forming backside contact plugs (also referred to as backside contacts) in the recesses left by the removed sacrificial regions. Through the pre-formation of the sacrificial regions, the backside contact plugs may be accurately aligned to the lower source/drain regions. The overlay shift of the backside contact plugs from the lower source/drain regions is thus reduced.

It is appreciated that while Gate-All-Around (GAA) transistors (such as nanostructure-FETs) are discussed, the concept of the present disclosure can also be applied to the formation of backside contact of CFETs formed of other types of transistors such as planar transistors, Fin Field-Effect Transistors (FinFETs), and the like. Throughout the description, the terms “FET” and “transistor” are used interchangeably.

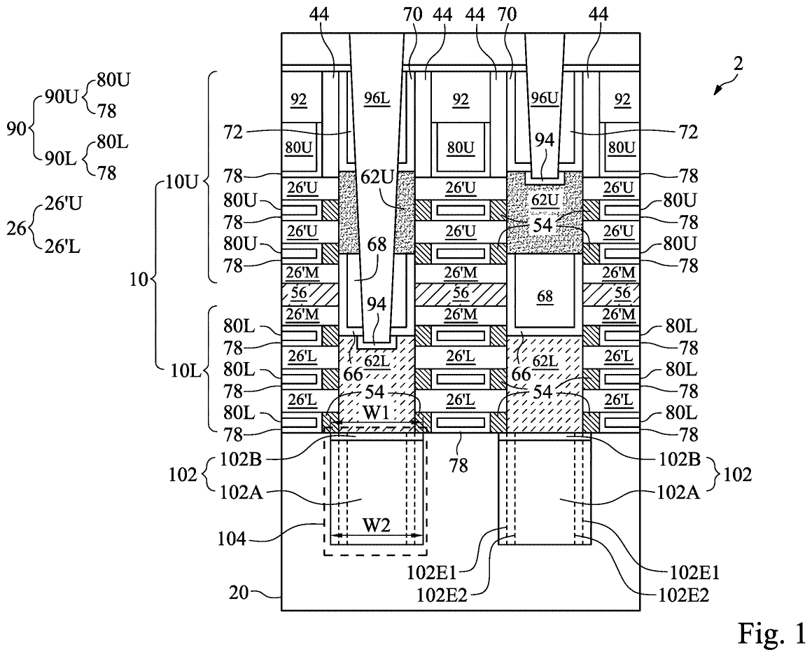

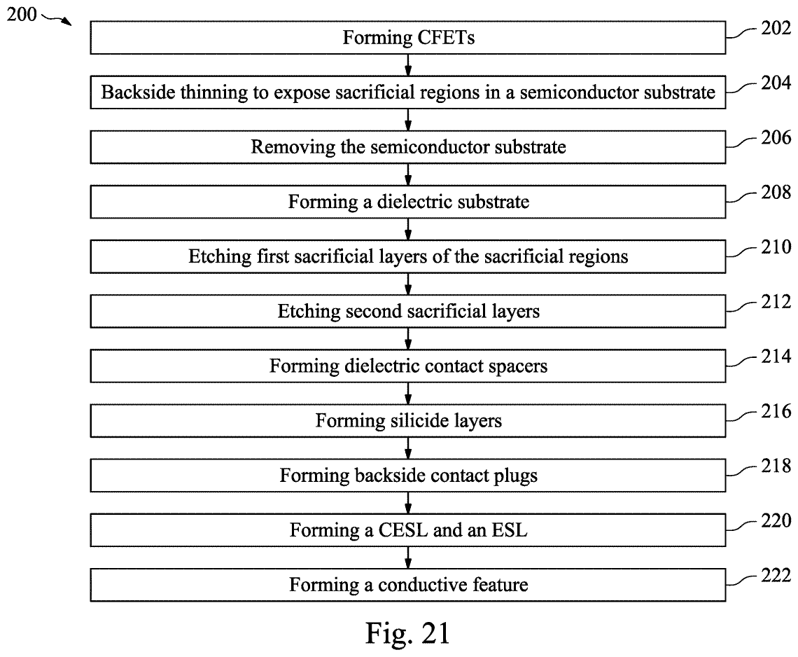

FIG. 1 illustrates the formation of an example CFET 10 (including FETs (transistors) 10U and 10L) in accordance with some embodiments. The respective process is illustrated as process 202 in the process flow 200 as shown in FIG. 21. CFETs may include vertically stacked FETs. For example, CFET 10 may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

As shown in FIG. 1, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor, or the like, or combinations thereof.

In the illustrated example, each of the upper FET 10U and lower FET 10L include two semiconductor layers 26′U and 26′L, respectively, as the channels. It should be appreciated that the upper FET 10U and lower FET 10L may include any number of channel regions such as 1, 2, 3, or more. The portions of the gate stack 90 that are overlying and/or underlying the channel regions 26 form multilayer stacks with the corresponding channel regions 26′U and 26′L.

Gate stacks 90 (including upper gate stacks 90U and lower gate stacks 90L) are formed between semiconductor layers 26. Upper gate stacks 90U includes gate dielectrics 78 and upper gate electrodes 80U. Lower gate stacks 90L includes gate dielectrics 78 and lower gate electrodes 80L. Gate dielectrics 78 encircle (when viewed in side views) the respective semiconductor nanostructures 26. Gate electrodes 80 (including a lower gate electrode 80L and an upper gate electrode 80U) are over the gate dielectrics 78. Dielectric isolation layers 56 are formed to isolate the gate stack 90U of the upper FETs 10U from the gate stack 90L of the lower FETs 10L. Dummy semiconductor layers 26′M may be formed to contact dielectric isolation layers 56.

Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context.

Inner spacers 54, which are dielectric spacers, are formed on the opposing sides of the portions of gate stacks 90, which portions are between semiconductor layers 26. Inner spacers 54 electrically insulate the source/drain regions 62L and 62U from the corresponding parts of gate stacks 90 to prevent and reduce leakage.

Gate spacers 44 are formed over the multilayer stacks and on the sidewalls of gate stacks 90. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as Chemical Vapor Deposition (CVD), Atomic Layer Deposition (ALD), or the like.

Epitaxial source/drain regions 62L and 62U are formed laterally between the multilayer stacks that comprise channel regions 26 and gate stacks 90. Lower epitaxial source/drain regions 62L are formed over and contacting a substrate, which includes semiconductor substrate 20 and sacrificial regions 102. The lower epitaxial source/drain regions 62L are further in contact with the lower semiconductor nanostructures 26′L and are not in contact with the upper semiconductor nanostructures 26′U.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants

A first contact etch stop layer (CESL) 66 and a first ILD 68 are formed over the lower epitaxial source/drain regions 62L. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like. The first CESL 66 may be formed of a dielectric material having a high etching selectivity from the etching of the first ILD 68. For example, the first CESL 66 may comprise silicon nitride, silicon oxide, silicon oxynitride, or the like, which may be formed by any suitable deposition process, such as CVD, ALD, or the like.

Upper epitaxial source/drain regions 62U are formed overlapping the first CESL 66 and the first ILD 68, and overlapping the lower source/drain regions 62L. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant.

A second CESL 70 and a second ILD 72 are formed over the upper epitaxial source/drain regions 62U. The materials may be similar to, and may be the same as or different from, the materials and the formation methods of first CESL 66 and first ILD 68, respectively, and are not discussed in detail herein.

Gate masks 92 are formed over the gate stacks 90. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72. More dielectric layers (as illustrated but not marked) such as etch stop layers, inter-layer dielectric, or the like, may be formed over gate masks 92 and the second ILD 72.

Silicide regions 94 and source/drain contact plugs 96U and 96L are formed to electrically couple to the upper source/drain region 62U and lower source/drain region 62L, respectively. The contact plug 96L may penetrate through upper source/drain region 62U to reach the lower source/drain region 62L. While not illustrated, in accordance with some embodiments, lower source/drain contact plug 96L may be encircled by a dielectric liner. The source/drain contact plugs 96L thus may be electrically decoupled from the upper source/drain region 62U it penetrates through.

In accordance with alternative embodiments, no dielectric liner is formed to encircle the lower source/drain contact plug 96L. Accordingly, the lower source/drain contact plug 96L may further be electrically coupled to the upper source/drain region 62U, and may electrically interconnect the upper source/drain region 62U and the lower source/drain region 62L.

As further shown in FIG. 1, sacrificial regions 102 are formed in substrate 20, and are underlying, and overlapped by, lower source/drain regions 62L. In accordance with some embodiments, sacrificial regions 102 comprise semiconductor materials, and may include sacrificial layers 102A and 102B, wherein sacrificial layers 102B are between the sacrificial layers 102A and the overlying lower source/drain regions 62L. The sacrificial regions 102 may also be in physical contact with the lower source/drain regions 62L.

In accordance with some embodiments, the formation of sacrificial regions 102 is performed before the overlying CFETs 10 are formed. The formation of sacrificial regions 102 may be performed before or after the formation of Shallow Trench Isolation (STI) regions (not shown), which are formed under CFETs and used to separate neighboring CFETs from each other. The sacrificial regions 102 may also be formed when the wafer 2 is a blank wafer.

In accordance with some embodiments, the formation of sacrificial regions 102 include etching semiconductor substrate 20 to form recesses, and filling the recesses with desirable material(s). In accordance with some embodiments, sacrificial layers 102A comprise silicon germanium, and the germanium atomic percentage may be in the range between about 10 percent and about 40 percent. The formation process may include epitaxy, and hence sacrificial layers 102A may have crystalline structures.

Sacrificial layers 102A may not be doped with any p-type dopants (such as boron, indium, or the like) or n-type dopants (such as phosphorous, arsenic, or the like). Alternatively, sacrificial layers 102A may be in-situ doped with a p-type or an n-type dopant, so that it may help to balance the doping concentration of well regions. Doping sacrificial layers 102A may also prevent the dopant concentrations of the well regions undesirably reduced due to diffusion into the sacrificial regions 102 in the formation of the CFETs.

Sacrificial layers 102B are formed over sacrificial layers 102A. Sacrificial layers 102B comprise a material different from the materials of lower source/drain regions 62L and the material of sacrificial layers 102A. In accordance with some embodiments, sacrificial layers 102B comprise silicon and is free from germanium. Sacrificial layers 102B may further comprise a dopant such as boron. In accordance with alternative embodiments, sacrificial layers 102B comprise silicon germanium with a lower germanium atomic percentage than sacrificial layers 102A. Sacrificial layers 102B may also be formed through epitaxy, and hence also have a crystalline structure.

After the formation of sacrificial layers 102B, a planarization process such as a Chemical Mechanical Polish (CMP) process or a mechanical polish process may be performed to level the top surfaces of sacrificial layers 102B with the top surface of substrate 20. The resulting structure comprising the substrate 20 (which may be a semiconductor substrate) and the sacrificial regions 102 may also be referred to as a (composite) substrate.

In accordance with alternative embodiments, sacrificial regions 102 may comprise materials other than semiconductor materials. For example, sacrificial regions 102 may be formed or comprise dielectric materials. In accordance with some embodiments, the entire sacrificial regions 102 may be formed of a homogeneous dielectric material such as silicon nitride, silicon oxide, silicon oxynitride, or the like. In accordance with alternative embodiments, sacrificial regions 102 also comprise more than one layers such as sacrificial layers 102A and 102B. The corresponding sacrificial layers 102A and 102B may be formed of different dielectric materials selected from silicon nitride, silicon oxide, silicon oxynitride, silicon oxycarbide, and the like.

In accordance with yet alternative embodiments, sacrificial layers 102B are formed of a different type of material than sacrificial layers 102A. For example, sacrificial layers 102A may be formed of a semiconductor material different from the material of substrate 20, and sacrificial layers 102B may be formed of a dielectric material, so that sacrificial layers 102B may act as an effective etch stop layer in the subsequent removal of sacrificial layers 102A.

In accordance with some embodiments, sacrificial regions 102 are formed directly under both of the illustrated lower source/drain region 62L. In accordance with alternative embodiments, a sacrificial layer 102A is formed directly underlying and overlapped by source/drain region 62L. On the other hand, no sacrificial region 102 is formed in the dashed region 104. Alternatively stated, no sacrificial region 102 is formed directly underlying and joined to the lower source/drain region 62L that has already been electrically connected to the source/drain contact 96L. Since the lower source/drain region 62L has already been electrically connected from the front side, it is not necessary to form a backside contact plug in the dashed region 104.

In accordance with some embodiments, the widths of sacrificial regions 102 may be greater than the widths of the corresponding overlying lower source/drain regions 62L. The sacrificial regions 102 thus may laterally extend beyond the corresponding edges of lower source/drain regions 62L, as illustrated in FIG. 1 in an example.

In accordance with alternative embodiments, the widths of sacrificial regions 102 are equal to the widths of lower source/drain regions 62L. The edges 102E1 of sacrificial regions 102 may be vertically aligned to the corresponding edges of the corresponding overlying lower source/drain regions 62L. In accordance with yet alternative embodiments, the widths of sacrificial regions 102 are smaller than the widths of lower source/drain regions 62L, and the edges 102E2 of sacrificial regions 102 may be laterally recessed from the corresponding edges of lower source/drain regions 62L.

Since sacrificial regions 102 may be formed by etching and then filling substrate 20, sacrificial regions 102 may have top width W1 and bottom width W2 smaller than top width W1. The edges of sacrificial regions 102 thus may be straight and slanted.

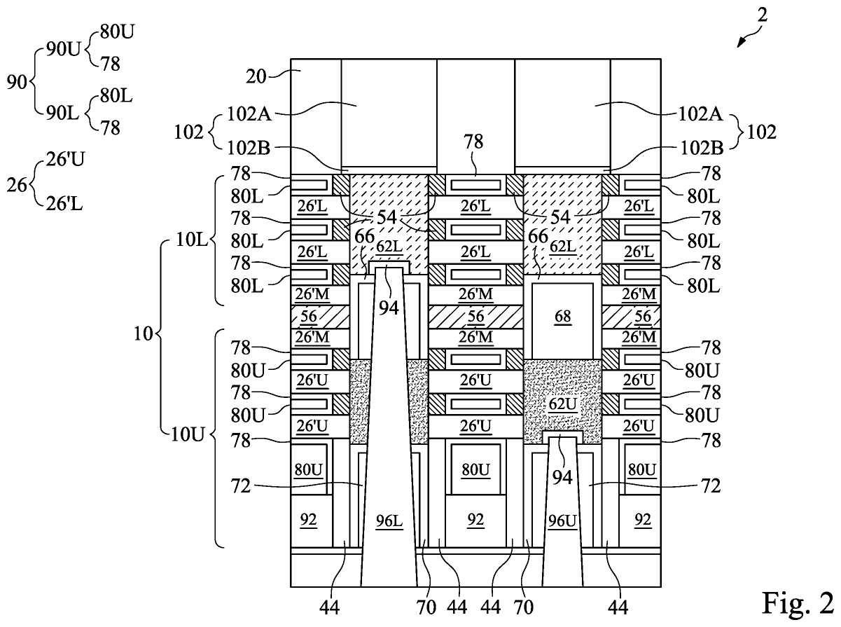

Referring to FIG. 2, wafer 2 is flipped upside down. A backside thinning process such as a CMP process or a mechanical grinding process is performed to remove some portions of substrate 20. The respective process is illustrated as process 204 in the process flow 200 as shown in FIG. 21. Sacrificial regions 102 are thus revealed.

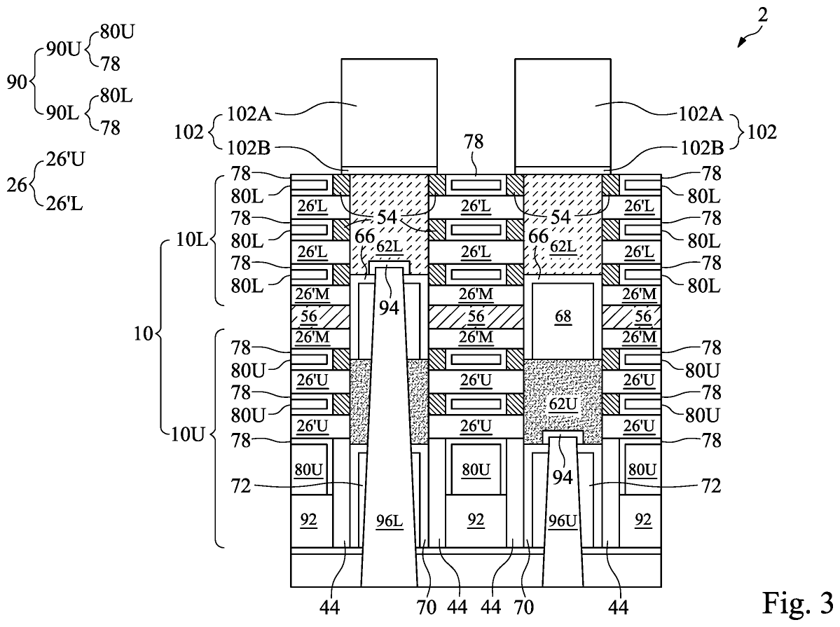

Next, as shown in FIG. 3, substrate 20 is removed through an etching process. The respective process is illustrated as process 206 in the process flow 200 as shown in FIG. 21. After the etching processes, inner spacers 54 and gate dielectrics 78 are exposed. The etching process is selective, so that substrate 20 is removed, while the sacrificial regions 102 are left unremoved. The etching process is also selective, so that inner spacers 54 and gate dielectrics 78 are not damaged.

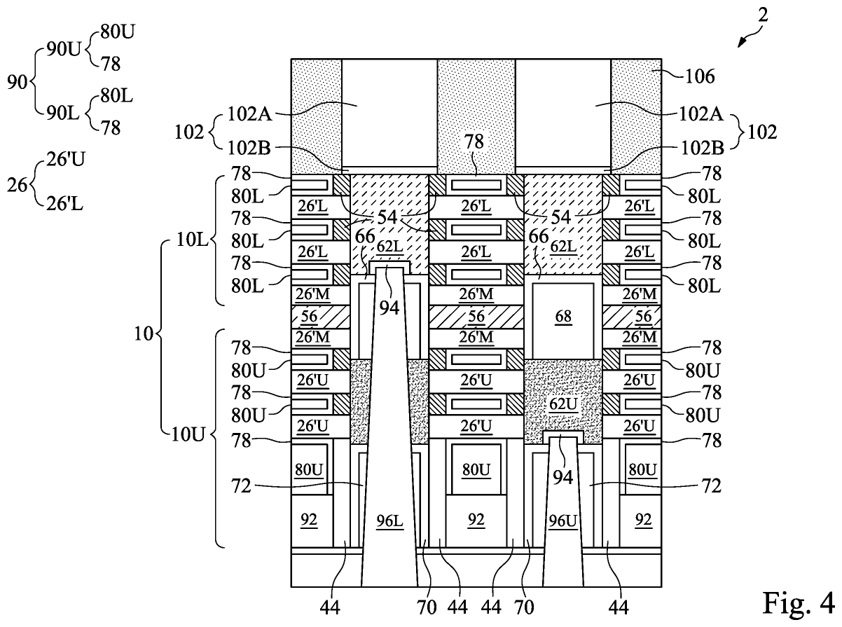

FIG. 4 illustrates the formation of dielectric layer 106, which is also referred to as dielectric substrate 106. The respective process is illustrated as process 208 in the process flow 200 as shown in FIG. 21. The formation process includes depositing a dielectric material until sacrificial regions 102 are fully embedded in the dielectric material, with substantially all surfaces of the dielectric material being higher than the top surfaces of sacrificial regions 102. In accordance with some embodiments, dielectric layer 106 comprises silicon oxide, silicon nitride, silicon oxynitride, silicon oxycarbide, silicon oxy-carbo-nitride, or the like. The deposition process may be performed through ALD, CVD, Plasma Enhanced Chemical Vapor Deposition (PECVD), or the like.

Next, a planarization process such as a CMP process or a mechanical grinding process is performed to remove the portions of the dielectric material over sacrificial regions 102. The top surfaces of sacrificial regions 102 are thus exposed again. The remaining dielectric material thus forms dielectric layer 106.

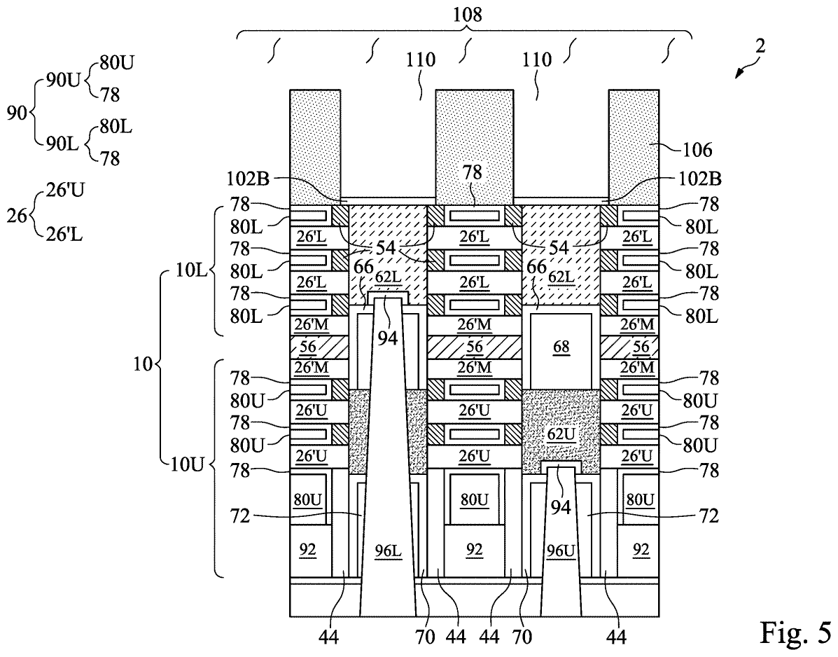

FIG. 5 illustrates an etching process 108 to remove sacrificial layers 102A and to form contact openings 110. The respective process is illustrated as process 210 in the process flow 200 as shown in FIG. 21. The etching process 108 may be performed through a dry etching process, which may be an isotropic etching process or an anisotropic etching process. Contact openings 110 are thus formed in dielectric layer 106. The etching process may also be performed through a wet etching process. The etching chemical (gas or wet solution) is selected to attack sacrificial layers 102A, but not dielectric layer 106. The etching rate of sacrificial layers 102B is also lower than the etching rate of sacrificial layers 102A. Accordingly, sacrificial layers 102B are used as etch stop layers to stop the etching process 108.

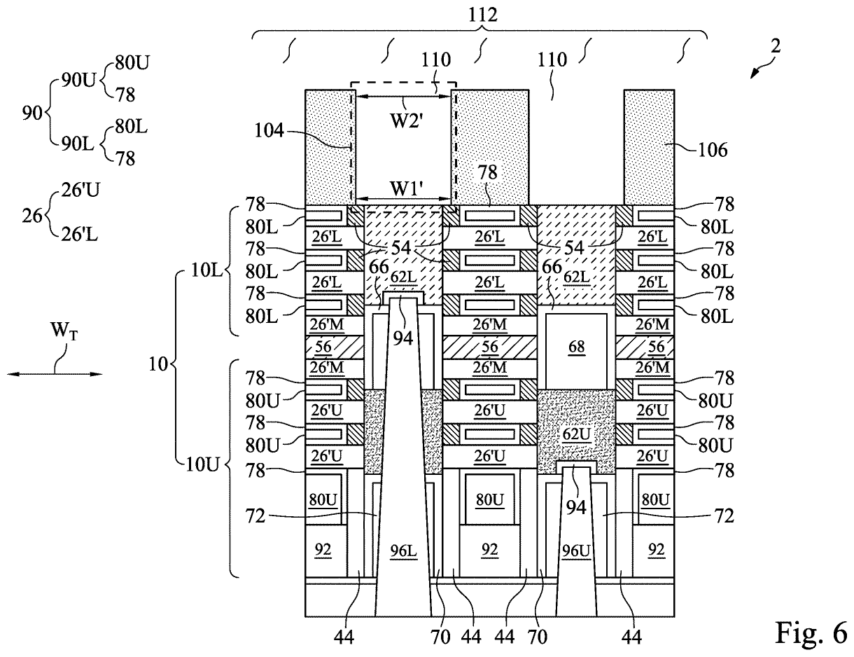

Referring to FIG. 6, an etching process 112 is performed, so that sacrificial layers 102B are removed, exposing the underlying lower source/drain regions 62L. The respective process is illustrated as process 212 in the process flow 200 as shown in FIG. 21. The etching process 112 may be a dry etching process, which may be an isotropic etching process. Alternatively, the etching process 112 may be a wet etching process.

As shown in FIG. 6, the openings 110 may have bottom width W1′ and top width W2′. Since the bottom width W1′ and top width W2′ are determined by (and may be equal to) the top width W1 (FIG. 1) and bottom Width W2, top width W2′ may be smaller than bottom width W1′. The edges of dielectric layer 106 facing openings 110 may also be slanted and straight.

In the embodiments in which the dashed region 104 has no sacrificial region 102 formed, the opening 110 in the dashed region 104 in FIG. 6 will also not be formed. Instead, the dashed region 104 will have the dielectric layer 106 therein, which covers the respective underlying source/drain region 62L.

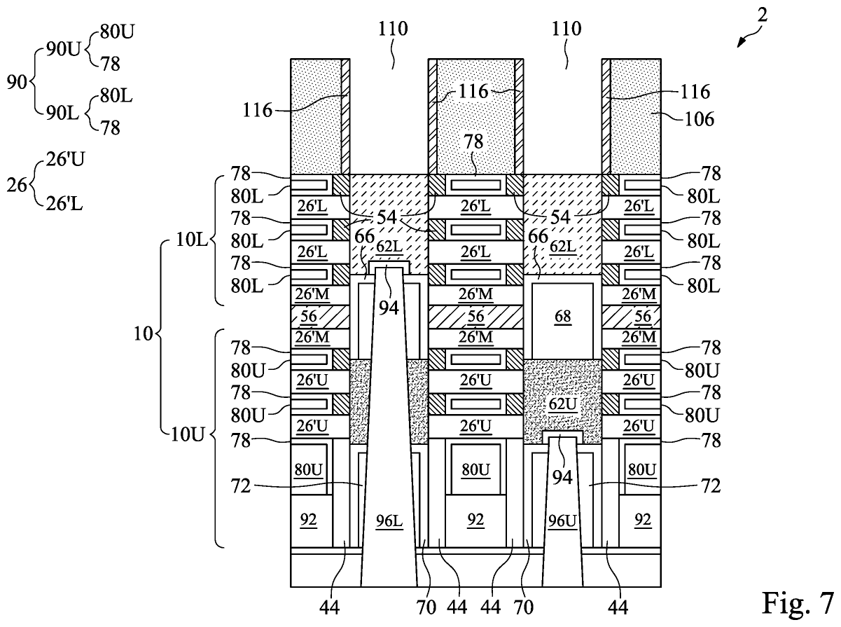

Referring to FIG. 7, dielectric contact spacers 116 are formed in contact openings 110, and on the sidewalls of dielectric layer 106. The respective process is illustrated as process 214 in the process flow 200 as shown in FIG. 21. In accordance with some embodiments, the formation of dielectric contact spacers includes a conformal deposition process such as CVD or ALD to form a conformal dielectric layer. The material of dielectric contact spacers 116 may comprise silicon oxide, silicon nitride, silicon oxynitride, silicon oxy carbo-nitride, or the like. Dielectric contact spacers 116 may also have a dielectric constant (k value) greater than 3.9, so that it has good isolation ability. The candidate materials may include AlₓO_{y}, HfO₂, or the like. The thickness of dielectric contact spacers 116 may be in the range between about 2 nm and about 6 nm, for example.

After the deposition of the conformal dielectric layer, an anisotropic etching process is performed, so that the horizontal portions of the conformal dielectric layer are removed, and the vertical portions of the dielectric conformal layer inside contact openings 110 are left to form dielectric contact spacers 116. Dielectric contact spacers 116 may form rings encircling contact openings 110 when viewed from the top of wafer 2.

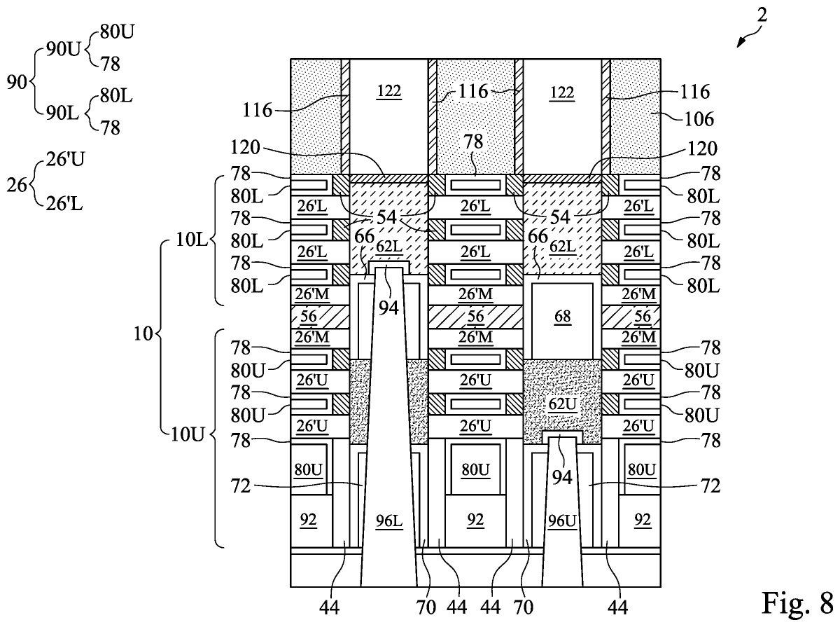

Depending on the widths of sacrificial regions 102, as discussed, the bottom surfaces of dielectric contact spacers 116 may contact one or more of several possible regions (materials). In accordance with some embodiments, the bottom surfaces of dielectric contact spacers 116 contact the top surfaces of inner spacers 54, and may or may not contact the top surfaces of lower source/drain regions 62L. Due t0 the accurate alignment of the subsequently formed backside contact plugs 122 (FIG. 8) to the lower source/drain regions, it is possible to expand the width of the backside contact plugs without the risk of the problems of overlay shift. The widths of contact openings 110 may be greater than, equal to, or smaller than the corresponding widths of lower source/drain regions 62L.

In accordance with some embodiments, the bottom surfaces of dielectric contact spacers 116 contact the top surfaces of lower source/drain regions, and are not in contact with the top surfaces of inner spacers 54. The widths of contact openings 110 are thus smaller than the corresponding widths of lower source/drain regions 62L.

Referring to FIG. 8, silicide layers 120 are formed on the top surfaces of lower source/drain regions 62L. The respective process is illustrated as process 216 in the process flow 200 as shown in FIG. 21. The formation process may include depositing a metal layer (not shown), for example, using a conformal deposition process such as Physical Vapor Deposition (PVD). A barrier layer (not shown), which may be a metal nitride layer such as a titanium nitride layer or a tantalum nitride layer, is then deposited over the metal layer. An annealing process is then performed to react the metal layer with the silicon (and germanium, if any) in lower source/drain regions 62L. Source/drain silicide layers 120 are thus formed. The annealing process may be performed through Rapid Thermal Anneal (RTA), furnace anneal, or the like.

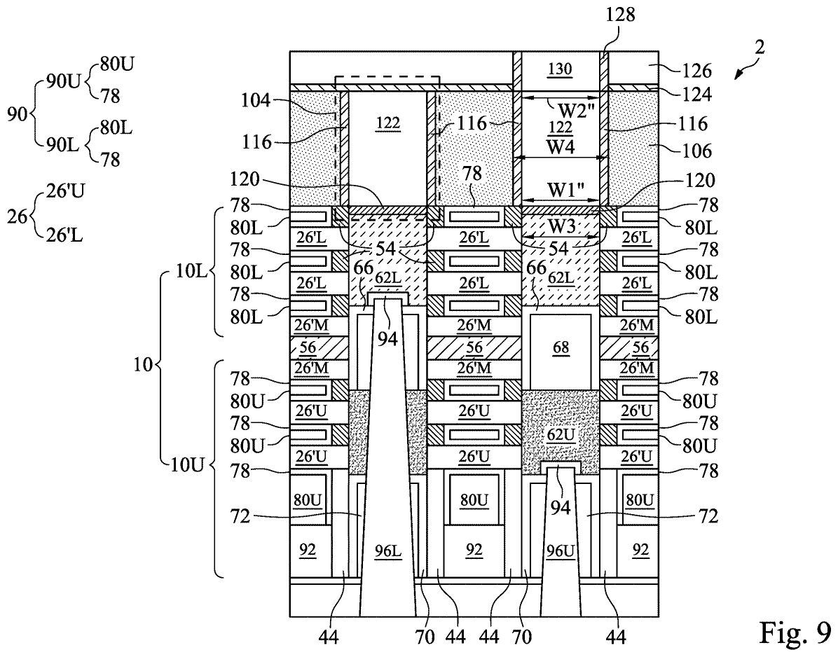

In accordance with some embodiments, as shown in FIGS. 5, 6, and 8, sacrificial layers 102B are removed, and silicide layers 120 are formed by reacting metal with lower source/drain regions 62L. In accordance with alternative embodiments, the sacrificial layers 102B are not removed, and will remain in the structures shown in FIGS. 6 and 7. The silicide layers 120 as shown in FIGS. 8 and 9 thus may be formed by reacting metal with sacrificial layers 102B (and possibly with lower source/drain regions 62L also), which may be silicon layers.

The barrier layer and the remaining metal layer may then be removed. Next, backside contact plugs 122 are formed to fill contact opening 110 and to electrically connect to silicide layers 120. The respective process is illustrated as process 218 in the process flow 200 as shown in FIG. 21. In accordance with some embodiments, the formation of the backside contact plugs 122 may include forming a barrier layer, which may comprise titanium nitride, tantalum nitride, or the like. Next, a metallic material is deposited over and in contact with the barrier layer. The metallic material may include tungsten, cobalt, or the like. A planarization process such as a CMP process or a mechanical grinding process is then performed to remove excess portions of barrier layer and the metallic material, leaving backside contact plugs 122.

Referring to FIG. 9, etch stop layer 124 and dielectric layer 126 are formed. The respective process is illustrated as process 220 in the process flow 200 as shown in FIG. 21. Etch stop layer 124 may comprise AlN, AlO, SiOC, or the like, or multilayers thereof. Dielectric layer 126 may comprise silicon oxide, silicon nitride, silicon oxynitride, silicon carbide, or the like.

A conductive feature 130 such as a metal line or a metal via is then formed over and contacting backside contact plug 122. The respective process is illustrated as process 222 in the process flow 200 as shown in FIG. 21. Dielectric liner 128 may be formed to encircle conductive feature 130 in accordance with some embodiments. In accordance with alternative embodiments, dielectric liner 128 is not formed.

In accordance with some embodiments, conductive feature 130 is formed of a homogeneous conductive material such as tungsten, cobalt, aluminum, or the like. In accordance with alternative embodiments, conductive feature 130 includes a conductive barrier and a conductive region over the conductive barrier layer. The conductive barrier may comprise Ti, TiN, Ta, TaN, or the like. The conductive region may comprise copper. The formation process of conductive feature 130 may include a damascene process.

It is appreciated that the backside contact plug 122 in the dashed region 104 may not be used for conducting current. Since the lower source/drain region 62L on the left side of FIG. 9 is electrically connected to source/drain contact plug 96L, the current flowing through the lower transistor 10L on the left side of FIG. 9 is conducted through source/drain contact plug 96L. The backside contact plug 122 in the dashed region 104 may have the same voltage as that of respective underlying lower source/drain region 62L. The currents flowing through the lower source/drain region 62L on the left side of FIG. 9, however, will not flow through the backside contact plug 122 in the dashed region 104.

In accordance with some embodiments, the entire top surface of the backside contact plug 122 in the dashed region 104 is in contact with etch stop layer 124, and currents also cannot flow through the respective backside contact plug 122. Alternatively stated, the backside contact plug 122 in the dashed region 104 is a terminal feature of currents and voltages, at which the currents and voltage terminate.

In accordance with alternative embodiments, the backside contact plug 122 in the dashed region 104 is further connected to the backside metal lines (not shown). Accordingly, the backside contact plug 122 in the dashed region 104 is electrically connected to the contact plug 96L, and currents may flow between the backside contact plug 122 and the contact plug 96L, with lower source/drain region 62L acting as an interconnector.

In accordance with some embodiments, the bottom width W1″ of backside contact plug 122 may be greater than, equal to, or smaller than the top width W3 of lower source/drain regions 62L. The outer width W4 of the combined features including dielectric contact spacer 116 and backside contact plug 122 may also be greater than, equal to, or smaller than the top width W3 of lower source/drain regions 62L. Since backside contact plugs 122 are formed based on the sacrificial regions 102 (FIG. 1), the top width W2″ of backside contact plugs 122 may be smaller than or equal to the bottom width W1″ of backside contact plugs 122.

In accordance with alternative embodiments in which no contact opening 110 is formed in region 104 (FIG. 6), in the dashed region 104, no silicide layer 120 and backside contact plug 122 are formed. Accordingly, dielectric layer 106 will be in physical contact with the top surface of lower source/drain region 62L to form an interface. The electrical connection to the lower source/drain region 62L is also through source/drain contact plug 96L.

The formation of the backside contact plugs 122 is self-aligned to the sacrificial regions 102, which are vertically aligned to the lower source/drain regions 62L accurately. Accordingly, the backside contact plugs 122 are aligned to the lower source/drain regions 62L without the concern of overlay shift and misalignment. It is also possible to form wider backside contact plugs 122 without the risk of misalignment (which causes electrical shorting of lower source/drain regions 62L to metal gates). The backside contact plug 122 thus may be formed to laterally extend beyond opposing edges of the respective underlying lower source/drain regions 62L. If, however, the formation of backside contact plugs 122 are not through the self-alignment process according to the embodiments of the present embodiment, the bottom width W1″ of the backside contact plugs 122 would have to be formed smaller than the top width W3 of the lower source/drain regions 62L to leave some process margin for process variation and overlay shift.

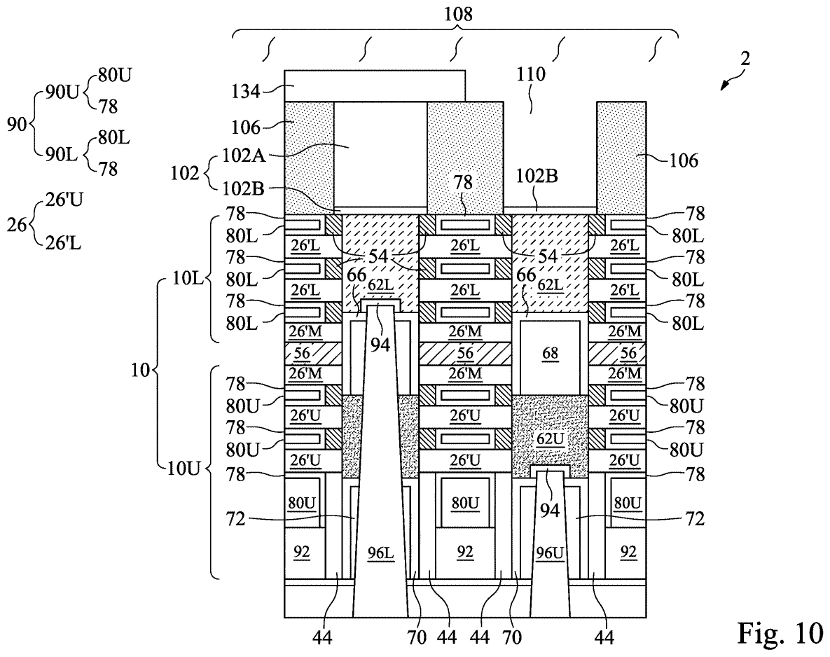

FIGS. 10 through 16 illustrate the formation of the backside contact plugs in accordance with alternative embodiments of the present disclosure. These embodiments are similar to the embodiments shown in FIGS. 1 through 9, except that two backside contact plugs are formed in separate processes and thus may extend to different heights. Unless specified otherwise, the materials, the structures, and the formation processes of the components in these embodiments (and other embodiments throughout the disclosure) are essentially the same as the like components denoted by like reference numerals in the preceding embodiments. The details regarding the materials, the structures, and the formation processes provided in each of the embodiments throughout the description may be applied to any other embodiment whenever applicable.

The initial process of these embodiments are essentially the same as shown in FIGS. 1 through 4. Next, as shown in FIG. 10, etching mask 134 is formed and patterned. Etching mask 134 may comprise a patterned photoresist, and may or may not include hard masks. Etching mask 134 covers the sacrificial region 102 on the left side of FIG. 10, and leaves some other sacrificial regions 102 such as the sacrificial region 102 on the right side of FIG. 4 exposed.

Next, as also shown in FIG. 10 etching process 108 is performed to remove the right-side sacrificial layer 102A (as shown FIG. 4), exposing the underlying sacrificial layer 102B, which acts as an etch stop layer. Contact opening 110 is thus formed. The sacrificial layer 102B is thus exposed. The etching mask 134 is then removed. In the removal of etching mask 134, sacrificial layer 102B protects the underlying lower source/drain region 62L.

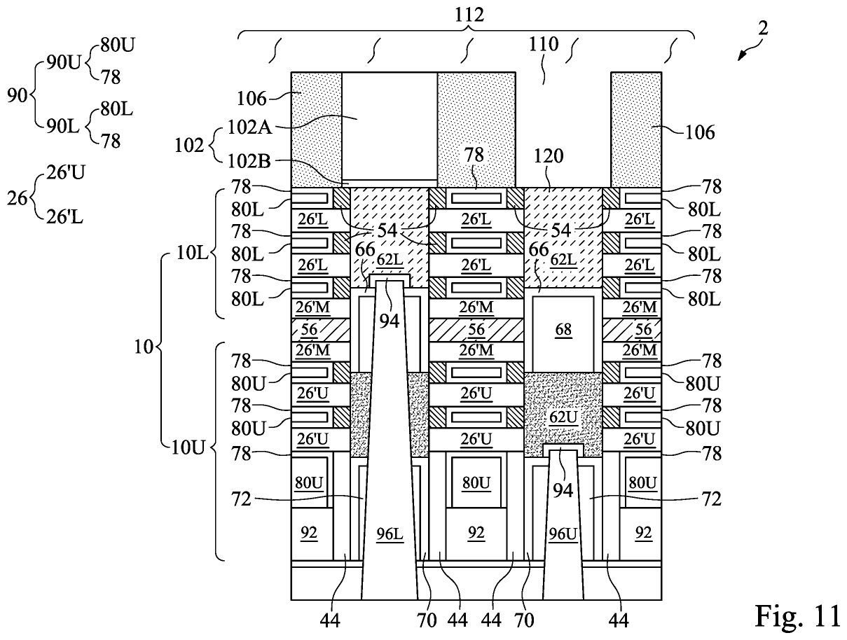

FIG. 11 illustrates the etching process 112, through which sacrificial layer 102B is removed, exposing the underlying lower source/drain region 62L, which also acts as an etch stop layer due to the difference between the materials of the sacrificial layer 102B and the lower source/drain region 62L.

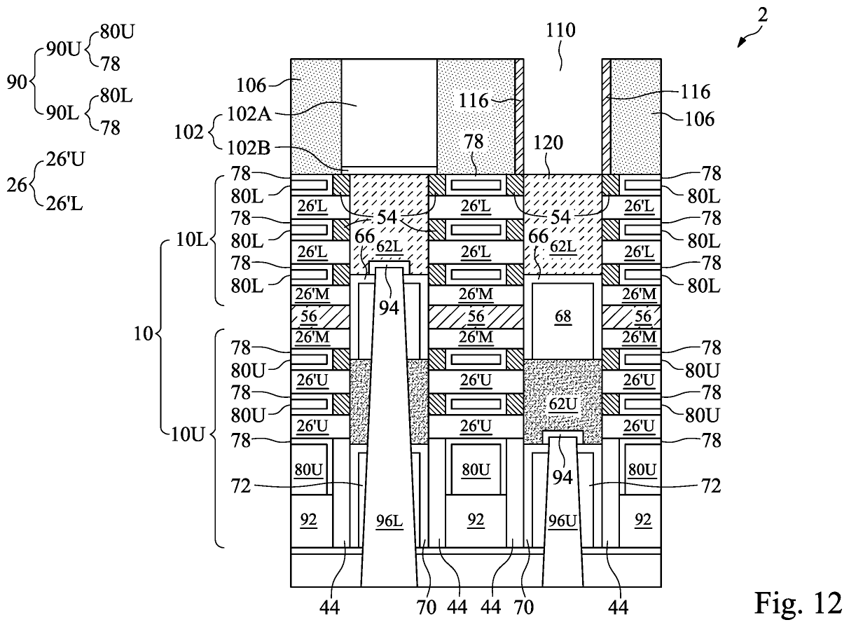

Next, as shown in FIG. 12, dielectric contact spacer 116 is formed, which includes performing a conformal deposition process to deposit a dielectric layer, and etching the dielectric layer through an anisotropic etching process.

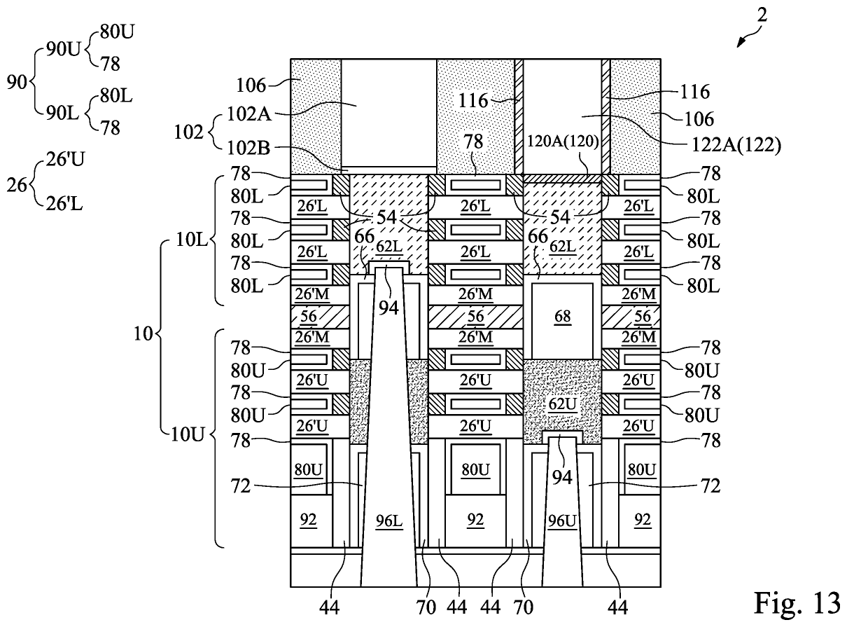

FIG. 13 illustrates the formation of silicide layer 120 (also referred to as silicide layer 120A), and the backside contact plug 122 (also referred to as backside contact plug 122A). The materials, the structures, and the formation processes are discussed referring to the preceding embodiments, and are not repeated herein.

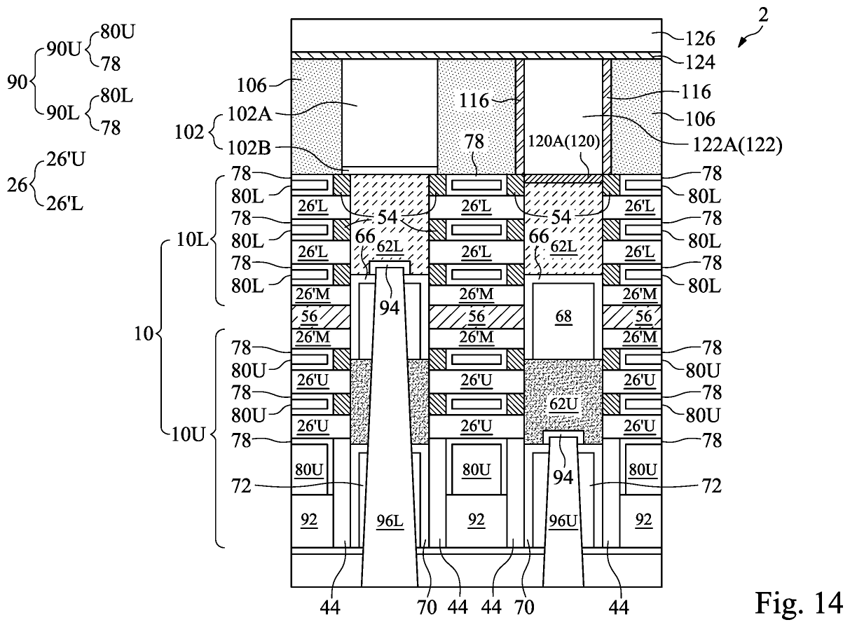

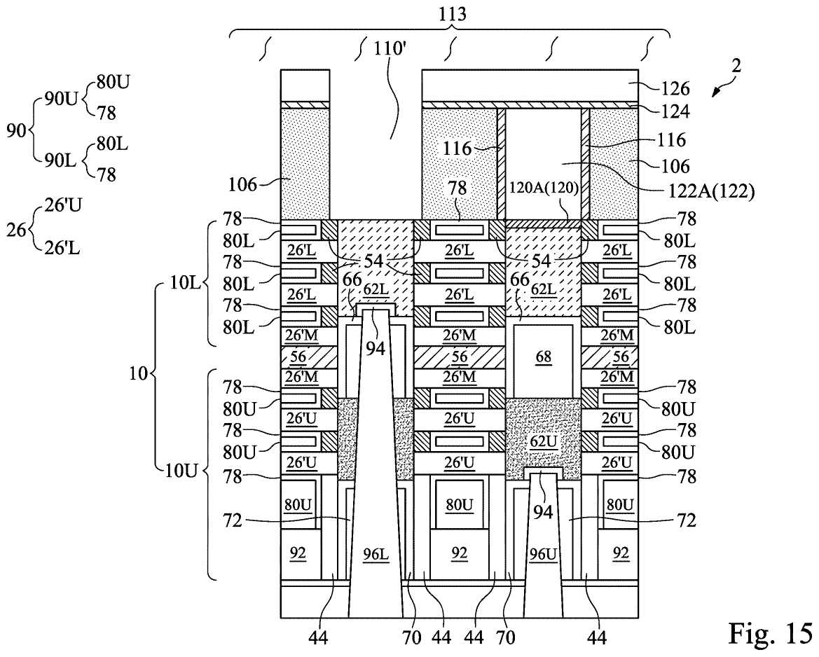

Next, referring to FIG. 14, etch stop layer 124 and dielectric layer 126 are deposited. Subsequently, as shown in FIG. 15, contact opening 110′ is formed through an etching process(es) 113. Contact opening 110′ comprises portions in dielectric layer 126 and etch stop layer 124, so that the underlying sacrificial region 102 (FIG. 14) is exposed. Next, the exposed sacrificial layer 102A is removed, followed by the etching process to removal sacrificial layer 1o2B, hence exposing lower source/drain region 62L. The etching of sacrificial region 102 may be performed using etch stop layer 124, sacrificial layer 102A, and sacrificial layer 102B as etch stop layers in a sequence of etching processes.

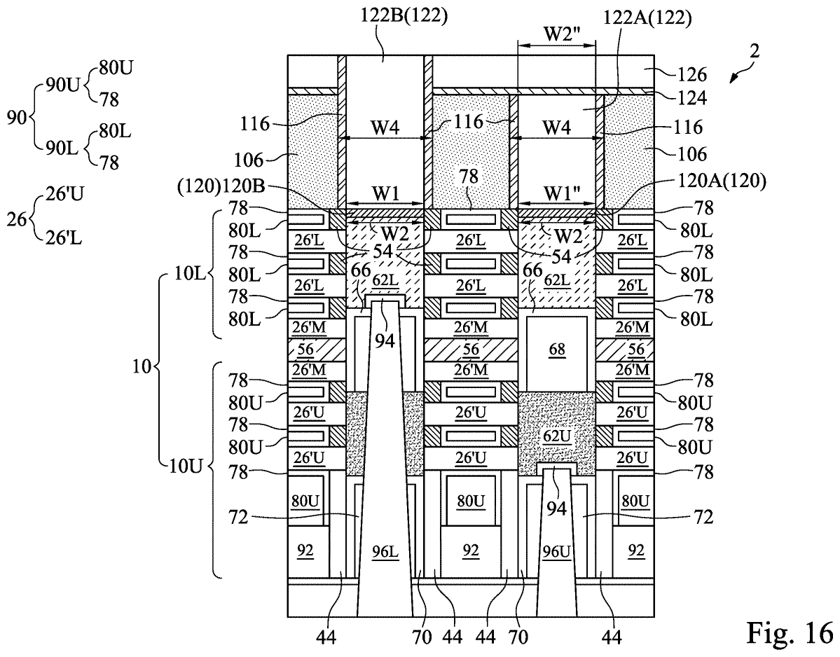

In a subsequent process, as shown in FIG. 16, silicide layer 120 (also refer to as silicide layer 120B) is formed on the top surface of lower source/drain region 62L. Backside contact plug 122 (also refer to as backside contact plug 122B) is also formed. Silicide layers 120A and 120B are individually and collectively referred to as silicide layers 120. Backside contact plugs 122A and 122B are individually and connectively referred to as backside contact plugs 122.

In accordance with some embodiments, the bottom width W1″ of backside contact plug 122, the top width W2″ of backside contact plugs 122, the top width W3 of lower source/drain regions 62L, and the outer width W4 of the combined features including dielectric contact spacer 116 and backside contact plug 122 may have the relationship same as what is discussed referring to FIG. 9.

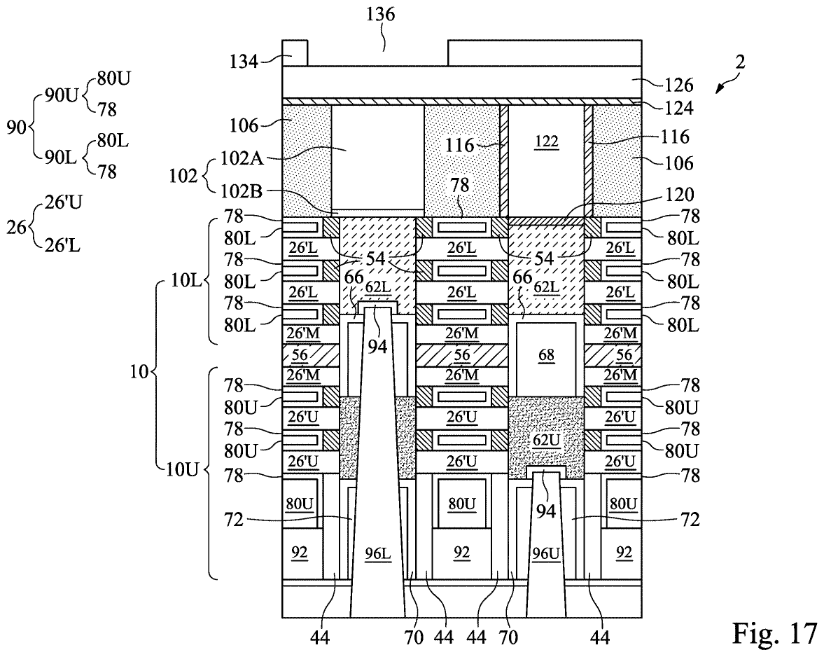

FIGS. 17 through 20 illustrate the formation of backside contact plugs in accordance with yet alternative embodiments of the present disclosure. These embodiments are similar to the embodiments shown in FIGS. 10-16, except that the backside contact plug is formed in a dual damascene structure, which dual damascene structure also includes metal lines for horizontal routing.

The initial processes of these embodiments are essentially the same as shown in FIGS. 1 through 4. The resulting structure is shown in FIG. 17. Next, etching mask 134 is formed and patterned, and opening 136 is formed in etching mask 134. Opening 136 extends laterally beyond the edges of the underlying sacrificial region 102 in opposing directions.

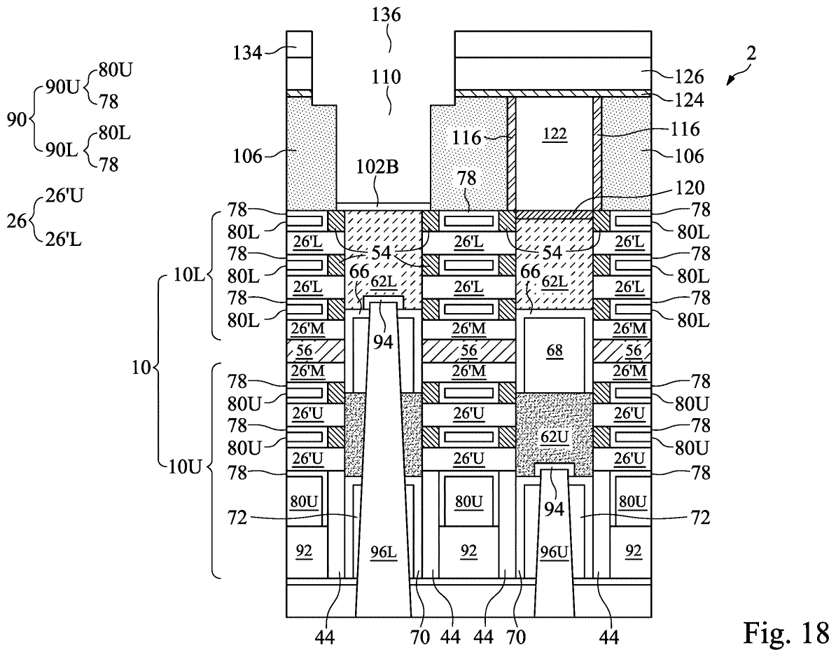

Next, as shown in FIG. 18, dielectric layer 126 is etched, and the etching is stopped on etch stop layer 124. The etching is anisotropic. Etch stop layer 124 is then etched to expose the underlying sacrificial layer 102A, and the etching may be anisotropic or isotropic.

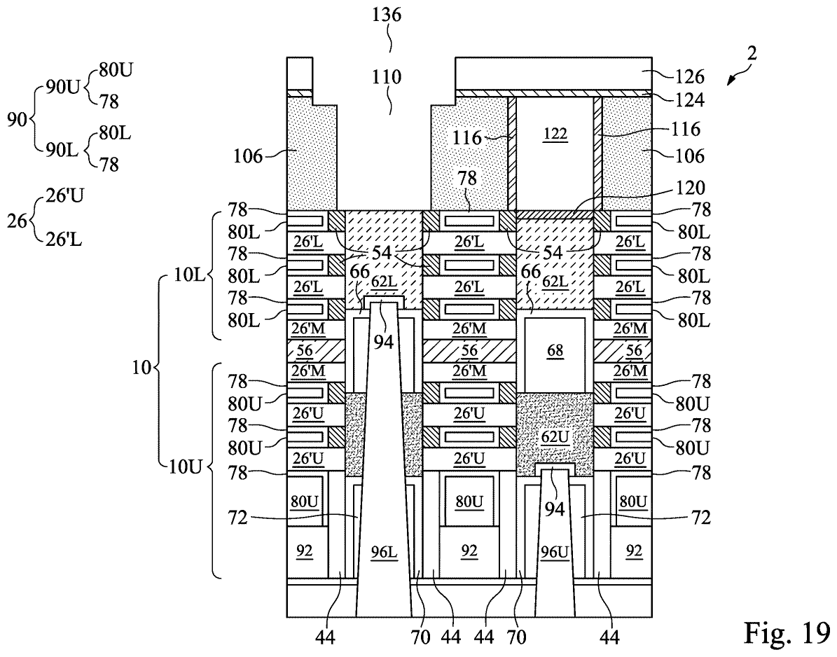

In accordance with some embodiments, etching mask 134 is removed, followed by the etching of sacrificial layer 102A to form contact opening 110. The resulting structure is shown in FIG. 19. In accordance with alternative embodiments, etch mask 134 is removed after the removal of sacrificial layer 102A, and before the removal of sacrificial layer 102B. During the removal of etching mask 134, sacrificial layer 102A or sacrificial layer 102B protects lower source/drain region 62L from being damaged.

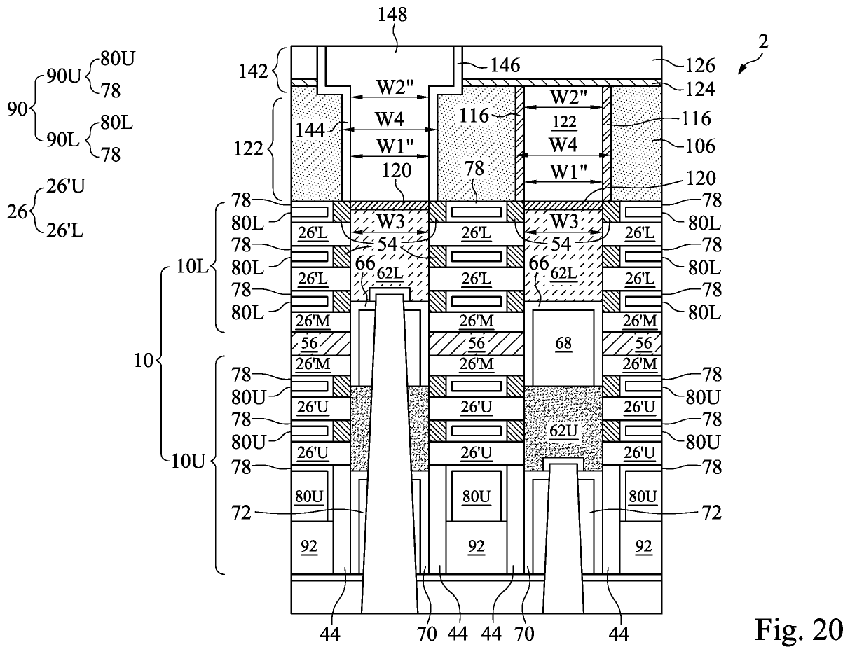

Referring to FIG. 20, metal line 142 and via 144 are formed. Via 144 also acts as the backside contact plug. In accordance with some embodiments, metal line 142 and via 144 include barrier layer 146 and metallic material 148 over barrier layer 146. Barrier layer 146 may comprise Ti, TiN, Ta, TaN, or the like. The metallic material 148 may comprise copper or other materials such as tungsten, cobalt, or the like.

In accordance with some embodiments, the bottom width W1″ of backside contact plug 122, the top width W2″ of backside contact plugs 122, the top width W3 of lower source/drain regions 62L, and the outer width W4 of the combined features including dielectric contact spacer 116 and backside contact plug 122 may have the relationship same as what is discussed referring to FIG. 9. The relationship of the relative values may apply to via 144 and backside contact plug 122.

In the embodiments as shown in FIGS. 10 through 20, sacrificial layers 102B (FIGS. 10, 14, and 18) may also be removed, or not removed, so that the remaining sacrificial layers 102B may be used for forming silicide layers 120.

The embodiments of the present disclosure have some advantageous features. By pre-forming sacrificial regions in a substrate, and lower source/drain regions are formed to be over and vertically aligned to the sacrificial regions, the backside contact plugs may be formed self-aligned to the sacrificial regions and thus vertically aligned to the lower source/drain regions. The alignment is thus accurate, and the problems such as source/drain to metal gate shorting or leakage is eliminated. By replacing semiconductor substrate with a dielectric layer, the adverse leakage from the backside contact plug to the substrate is also eliminated.

In accordance with some embodiments of the present disclosure, a method comprises forming a lower source/drain region over a substrate; forming a gate stack aside of the lower source/drain region; forming an upper source/drain region over the lower source/drain region; performing a backside thinning process to thin the substrate and to reveal a sacrificial region; removing the sacrificial region to reveal the lower source/drain region; and forming a backside contact plug to electrically connect to the lower source/drain region. In an embodiment, the removing the sacrificial region comprises removing a semiconductor region.

In an embodiment, the removing the semiconductor region comprises removing a silicon germanium layer. In an embodiment, the removing the sacrificial region further comprises, after the removing the semiconductor region, etching a silicon layer. In an embodiment, the removing the sacrificial region comprises isotropic etching processes. In an embodiment, the method further comprises, after the backside thinning process and before the sacrificial region is removed, removing a semiconductor substrate of the substrate; and forming a dielectric substrate to embed the sacrificial region therein.

In an embodiment, the sacrificial region is removed from the dielectric substrate. In an embodiment, the method further comprises, before the backside contact plug is formed, forming a dielectric contact spacer, wherein the backside contact plug is encircled by the dielectric contact spacer. In an embodiment, the gate stack comprises a lower portion aside of and contacting an inner spacer, and wherein the dielectric contact spacer contacts the inner spacer to form an interface. In an embodiment, the backside contact plug laterally extends beyond an edge of the lower source/drain region.

In accordance with some embodiments of the present disclosure, a method comprises forming a sacrificial region in a semiconductor substrate; forming a lower transistor comprising a lower source/drain region, wherein the lower source/drain region is over and contacting the sacrificial region; a gate stack; and a dielectric inner spacer between the gate stack and the lower source/drain region; forming an upper transistor comprising an upper source/drain region, wherein the upper source/drain region overlaps the lower source/drain region; forming a front-side contact plug over and electrically coupling to the upper source/drain region; thinning the semiconductor substrate to reveal the sacrificial region; replacing the semiconductor substrate with a dielectric substrate; removing the sacrificial region to form a recess in the dielectric substrate; and forming a backside contact plug in the recess to electrically couple to the lower source/drain region.

In an embodiment, the method further comprises forming a dielectric contact spacer in the recess, wherein the backside contact plug is encircled by the dielectric contact spacer. In an embodiment, the dielectric contact spacer is in contact with the dielectric inner spacer. In an embodiment, the backside contact plug physically contacts the dielectric inner spacer. In an embodiment, a portion of the backside contact plug forms an interface with the dielectric inner spacer. In an embodiment, the method further comprises forming a silicide layer, wherein the silicide layer is between the backside contact plug and the lower source/drain region.

In accordance with some embodiments of the present disclosure, a method comprises forming a lower source/drain region over a semiconductor substrate; forming a dielectric region over and contacting the lower source/drain region; forming an upper source/drain region over and contacting the dielectric region; thinning the semiconductor substrate from backside to reveal a sacrificial region; replacing the semiconductor substrate with a dielectric substrate; performing an isotropic etching process to remove the sacrificial region; and forming a backside contact plug in a space left by the isotropic etching process.

In an embodiment, the isotropic etching process comprises, in a first etching process, etching a first semiconductor layer. In an embodiment, the isotropic etching process further comprises, in a second etching process, etching a second semiconductor layer to reveal the lower source/drain region. In an embodiment, the sacrificial region comprises a crystalline semiconductor material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
etching a semiconductor substrate to form a first recess;
filling the first recess to form a first sacrificial region;
forming a first lower source/drain region overlapping the first sacrificial region;
forming a gate stack on a side of the first lower source/drain region;
forming a first upper source/drain region over the first lower source/drain region;
performing a backside thinning process to reveal the first sacrificial region; and
performing a replacing process to replace at least a portion of the first sacrificial region with a first backside contact plug.

2. The method of claim 1, wherein the replacing process comprises:
removing the portion of the first sacrificial region through etching to form an opening; and
depositing a conductive material into the opening.

3. The method of claim 2, wherein the removing the portion of the first sacrificial region comprises removing a silicon germanium layer.

4. The method of claim 3, wherein the removing the portion of the first sacrificial region further comprises, after the silicon germanium layer is removed, etching a silicon layer.

5. The method of claim 3, wherein after the portion of the first sacrificial region is removed, a silicon layer is exposed, and the method further comprises:
siliciding the silicon layer to form a silicide layer.

6. The method of claim 1, wherein the replacing process comprises an isotropic etching process to etch the first sacrificial region.

7. The method of claim 1 further comprising:
after the backside thinning process and before the replacing process, removing the semiconductor substrate; and
forming a dielectric substrate to embed the first sacrificial region therein.

8. The method of claim 7, wherein the first sacrificial region is removed at a time after the dielectric substrate is formed.

9. The method of claim 1 further comprising, before the first backside contact plug is formed, forming a dielectric contact spacer, wherein the backside contact plug is in the dielectric contact spacer.

10. The method of claim 1, wherein the backside thinning process further reveals a second sacrificial region formed of same materials as the first sacrificial region, and wherein at a time after the replacing process, the second sacrificial region remains.

11. A method comprising:
forming a first lower source/drain region and a second lower source/drain region over a semiconductor substrate;
thinning the semiconductor substrate from backside to reveal a first sacrificial region and a second sacrificial region, wherein the first sacrificial region is joined to the first lower source/drain region, and the second sacrificial region is joined to the second lower source/drain region;
performing a first removal process to remove the first sacrificial region and to form a first opening; and
forming a first backside contact plug in the first opening, wherein the first backside contact plug is electrically connected to the first lower source/drain region.

12. The method of claim 11 further comprising:
forming a first dielectric region and a second dielectric region over and contacting the first lower source/drain region and the second lower source/drain region, respectively; and
forming a first upper source/drain region and a second upper source/drain region over and contacting the first dielectric region and the second dielectric region, respectively.

13. The method of claim 11 further comprising replacing the semiconductor substrate with a dielectric substrate.

14. The method of claim 11, wherein the first removal process comprises an isotropic etching process.

15. The method of claim 11, wherein at a time the first removal process is ended, the second sacrificial region remains.

16. The method of claim 11 further comprising:
performing a second removal process to remove the second sacrificial region and to form a second opening, wherein the first removal process and the second removal process are separate processes; and
forming a second backside contact plug in the second opening, wherein the second backside contact plug is electrically connected to the second lower source/drain region.

17. The method of claim 11, wherein the first backside contact plug extends laterally beyond an edge of the first lower source/drain region.

18. A method comprising:
forming a sacrificial region in a semiconductor substrate, wherein the sacrificial region comprises:
a first sacrificial layer comprising a first material; and
a second sacrificial layer over the first sacrificial layer, wherein the second sacrificial layer comprises a second material different from the first material;
forming a source/drain region over and contacting the second sacrificial layer;
thinning the semiconductor substrate from backside, until the first sacrificial layer is exposed; and
removing the first sacrificial layer to form an opening, wherein the second sacrificial layer is used as an etch stop layer.

19. The method of claim 18, wherein the second sacrificial layer comprises silicon, and the method further comprises, after the first sacrificial layer is removed, siliciding the second sacrificial layer to form a silicide layer.

20. The method of claim 18 further comprising:
after the first sacrificial layer is removed, removing the second sacrificial layer; and
performing a silicidation process to convert a portion of the source/drain region as a silicide layer.
